(19) United States
(12) Patent Application Publication
(10) Pub. No.: US 2017/0125394 A1
(43) Pub. Date: May 4, 2017

(54) Wide Bandgap Junction Barrier Schottky Diode With Silicon Bypass

(71) Applicant: United Silicon Carbide, Inc., Monmouth Junction, NJ (US)

(72) Inventor: Anup Bhalla, Princeton Junction, NJ (US)

(21) Appl. No.: 15/333,622

(22) Filed: Oct. 25, 2016

Related U.S. Application Data
(60) Provisional application No. 62/248,010, filed on Oct. 29, 2015.

(51) Int. Cl. H01L 25/18; H01L 23/60; H01L 27/02

(52) U.S. Cl. CPC H01L 25/18; H01L 27/0255; H01L 23/60; H01L 29/872

(57) ABSTRACT

A silicon surge bypass diode is co-packaged with a high bandgap junction barrier Schottky diode. The co-packaged diodes may be used in a power circuits such as power factor correction circuits, converters, inverters circuit, motor drives, and protection circuits, for example. The high bandgap diode may be made of silicon carbide, gallium nitride, aluminum nitride, aluminum gallium nitride, and/or diamond, for example. The high bandgap diode may be formed by diode connecting a transistor, such as a high-electron-mobility transistor (HEMT). The high bandgap diode may be much smaller than the silicon diode. The package may have a common terminal for the diode cathodes, and separate terminals for the anodes of each diode.

### CROSS-REFERENCE TO RELATED APPLICATIONS

This application claims the benefit of U.S. Provisional Application No. 62/248,010, filed on Oct. 29, 2015, entitled “Wide Bandgap Junction Barrier Schottky Diode with Silicon Surge Bypass”, the content of which is hereby incorporated by reference in its entirety.

### FIELD OF THE DISCLOSURE

This disclosure is in the field of junction barrier Schottky (JBS) diodes and circuits incorporating JBS diodes. Devices integrating wide bandgap JBS diodes and silicon components are disclosed.

### BACKGROUND

High-current and high voltage devices made from wide bandgap materials such as silicon carbide (SiC), gallium nitride (GaN), aluminum nitride (AlN), aluminum gallium nitride (AlGaN), and diamond are useful in power electronic circuits, such as power factor correction (PFC) devices, DC-DC converters, DC-AC inverters, overcurrent and overvoltage protection circuits, and motor drives.

### SUMMARY OF THE INVENTION

A silicon surge bypass diode is co-packaged with a high bandgap junction barrier Schottky diode. The co-packaged diodes may be used in power circuits such as power factor correction circuits, converters, inverters circuit, motor drives, and protection circuits, for example. The high bandgap diode may be made of silicon carbide, gallium nitride, aluminum nitride, aluminum gallium nitride, and/or diamond, for example. The high bandgap diode may be formed by diode connecting a transistor, such as a high-electron-mobility transistor (HEMT). The high bandgap diode may be much smaller than the silicon diode. The package may have a common terminal for the diode cathodes, and separate terminals for the anodes of each diode.

This summary is provided to introduce a selection of concepts in a simplified form that are further described below in the detailed description. This summary is not intended to identify key features or essential features of the claimed subject matter, nor is it intended to be used to limit the scope of the claimed subject matter. Furthermore, the claimed subject matter is not limited to limitations that solve any or all disadvantages noted in any part of this disclosure.

### BRIEF DESCRIPTION OF THE DRAWINGS

The summary, as well as the following detailed description, is further understood when read in conjunction with the appended drawings. For the purpose of illustrating the invention, there are shown in the drawings exemplary embodiments of the invention; however, the invention is not limited to the specific methods, compositions, and devices disclosed.

FIG. 1 is a schematic of an example of a simple circuit where a boost diode is used in conjunction with a surge bypass diode.

FIG. 2 is a schematic of an example of a more complex circuit where a boost diode is used in conjunction with a surge bypass diode.

FIG. 3 is a graph of voltage and current over time for example circuits.

FIG. 4 shows a schematic of an example device including two diodes and a view of the diodes placed in a package.

FIG. 5 shows a view of an example device including a lateral diode co-packaged with another diode.

### DETAILED DESCRIPTION

A silicon surge bypass diode is co-packaged with a high bandgap junction barrier Schottky diode. The co-packaged diodes may be used in power circuits such as power factor correction circuits, converters, inverters circuit, motor drives, and protection circuits, for example. The high bandgap diode may be made of silicon carbide, gallium nitride, aluminum nitride, aluminum gallium nitride, and/or diamond, for example. The high bandgap diode may be formed by diode connecting a transistor, such as a high-electron-mobility transistor (HEMT). The high bandgap diode may be much smaller than the silicon diode in physical size and/or surge capacitor. The package may have a common terminal for the diode cathodes, and separate terminals for the anodes of each diode.

In a power factor or boost converter circuit, for example, the co-packaged high bandgap diode may be small compared to the silicon diode. This is due to the high bandgap diode not having to bear a large surge current. This has several advantages. A smaller physical size means both lower cost and lower switching capacitance. The latter means, in turn, that the circuit may operate faster and/or produce less waste heat. Packaging the devices together also uses less space. Further, a common-cathode configuration allows for the use of a three-terminal package.

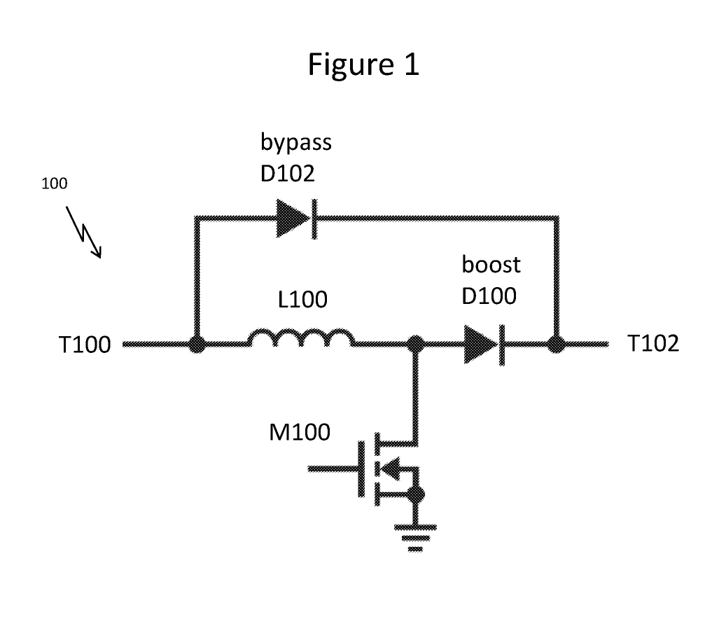

FIG. 1 is a schematic of an example of a simple circuit 100 where a boost diode D100 is used in conjunction with a surge bypass diode D102. This circuit 100 is a high frequency boost converter, such as is commonly used in power factor correction, e.g., for power supplies over 60 W. Power enters at terminal T100 and is boosted through inductor L100 by the switching of transistor M100. D102 is a surge bypass diode and made be made from a material such as silicon. D100 is a boost diode which feeds output terminal T102. D100 may be a junction barrier Schottky (JBS) diode made from a wide bandgap material. A JBS diode may be preferred since such diodes do not lead to reverse recovery losses in the transistor M100. A low capacitance in the boost diode D100 is beneficial for system efficiency, since it leads to lower turn-on losses in the transistor M100. JBS diodes with voltage ratings above 600V may be made from wide bandgap materials such as SiC, GaN, AlN, and diamond, among others, which allow for low on-state voltage drops and low capacitances with small die sizes, due to the excellent material properties of these wide bandgap semiconductors.

However, if an event occurs that forces a large surge current through the wide bandgap diode D100, it is prone to thermal destruction due to its small die size. Since Si die are much cheaper, and have a lower junction drop, a large die silicon bypass diode D102 can be used to sustain considerable surge current without damage.

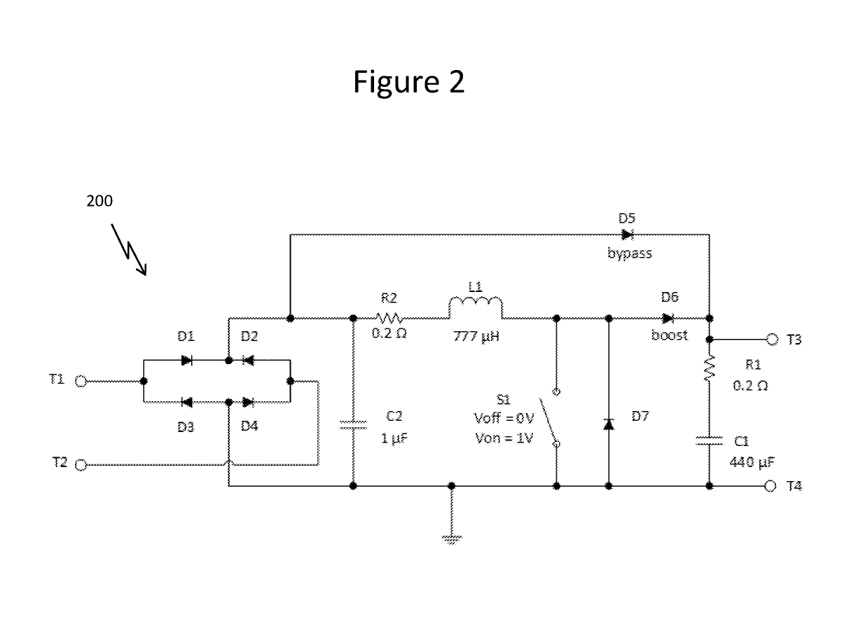

FIG. 2 is a schematic of an example of a more complex circuit 200 where a wide bandgap diode is used in conjunction with a silicon surge bypass diode. Here the input across terminals T1 and T2 is fed to a diode rectifier bridge consisting of diodes D1, D2, D3, and D4. The negative output of the bridge, at the anodes of D3 and D4, serves as the common connection for the output circuit, which is connected to terminal T4. The positive output of the bridge, at the cathodes of D1 and D2, is fed to the anode of a bypass diode D5, capacitor C2, and resistor R2. The cathode of D5 is connected to the circuit output terminal T3, which is loaded by a resistor R1 in series with a capacitor C1 which is connected to circuit common. The boost pathway feeds through resistor R2 through an inductor L1 to switch to common S1, and to the anode of a boost diode D6. In parallel with switch S1 is a diode D7. Diode D7 has its cathode connected to L1 and its anode connected to common.

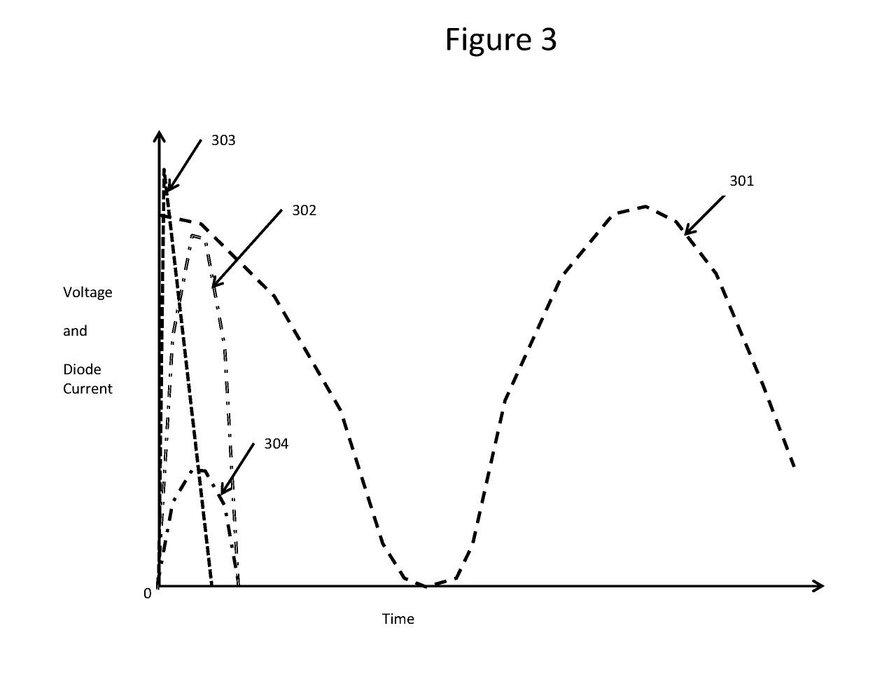

FIG. 3 is a graph of voltage and current over time for example circuits with and without a bypass diode. Consider, for example, the effect of a surge on a circuit such that the circuit of FIG. 2 under the following conditions: the voltage across output capacitor is at zero, and the input AC line voltage across input terminals T1 and T2 is abruptly turned on at the peak of the voltage cycle. In FIG. 3, curve 301 is the AC line voltage, which is switched on at time zero. If D5 is not present, a large pulsed current 302 flows in the boost diode D6. For the component values shown in FIG. 2, the peak of the boost diode current 302 may be 100 amperes.

If instead bypass diode D5 is in place, a much lower current 304 is seen through the boost diode D6. Most of the surge is born by the bypass diode D5 as current 303. The peak current through the boost diode D6 drops to under 40 amperes. This dramatically lowers the amount of energy absorbed by the die of D6. This means that a much smaller device may be used, which greatly reduces the cost of the device. The lower capacitance of the smaller wide bandgap diode die further improves circuit performance. The surge current in the bypass diode is large. However, this component may be a less costly silicon diode, and therefore a physically larger die without significantly impacting cost. The die size area of the bypass diode D5 may be, for example, 1.5 times larger than the die size area of the boost diode D6, or larger. Similarly, the surge current capacity of the bypass diode D5 may be 1.5 times the capacity of the boost diode, or more, even when the two diodes are comparable in physical size.

The inventors observe that in circuits such as those shown in FIGS. 1 and 2 that the surge bypass silicon diode and the wide bandgap diode share a common cathode. Therefore these components may be mounted in a common package as die on a common pad.

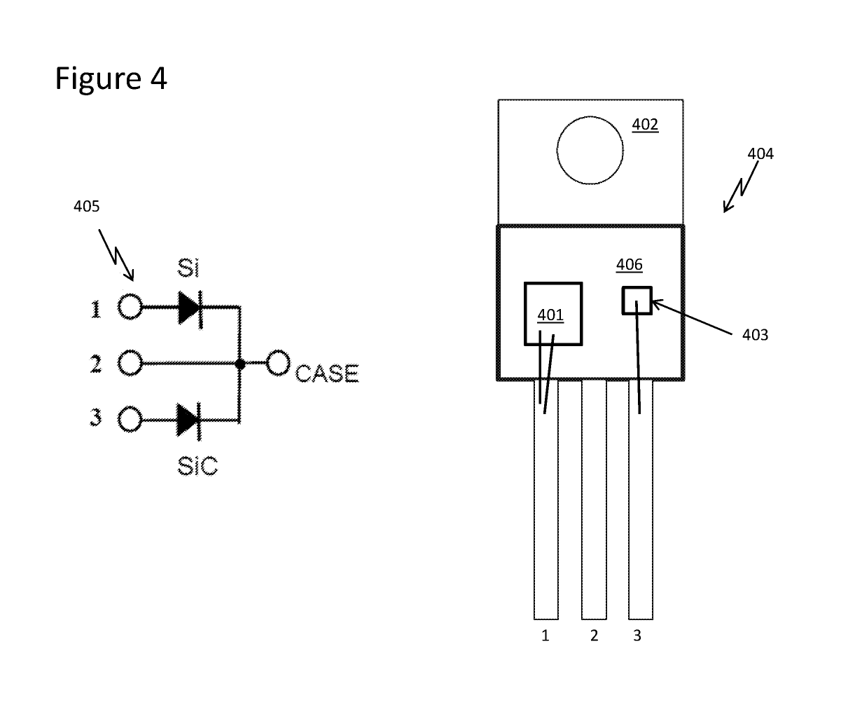

FIG. 4 shows a schematic 405 of an example device that includes a wide bandgap diode and a silicon diode, along with a view of the diodes placed in a package 404. The large silicon diode 401 is co-packaged with a small, wide bandgap JBS diode 403 on a common paddle 406 of a three-leaded TO-220 package 404. The cathodes of the silicon diode 401 and the JBS diode 403 are bonded to the common paddle 406. The silicon diode 401 may be a relatively large device and be used, for example, as a bypass diode in a PFC circuit. The wide bandgap JBS diode 403 may be used, for example, as a boost diode in a PFC circuit. Placing both devices into the same housing in the shown configuration saves space and cost, by eliminating one package.

The anode of the silicon diode 401 is brought out to pin 1 of the package. The anode of the JBS diode 403 is brought out to pin 3 of the package. The common paddle die pad area 406 may be made of copper. The die pad area 406 is connected to the common center pin 2 and to an exposed heat sink tab 402. The die pad area 406 is encapsulated to protect the diodes 401 and 403.

It will be appreciated that many similar configurations are possible. For example, other packages may be used, such as other through-hole packages like the TO-247 and/or surface mount packages. The common cathode configuration of the silicon die and the wide bandgap die is preferred. Any pin configuration may be used as long as the two anodes are provided separately.

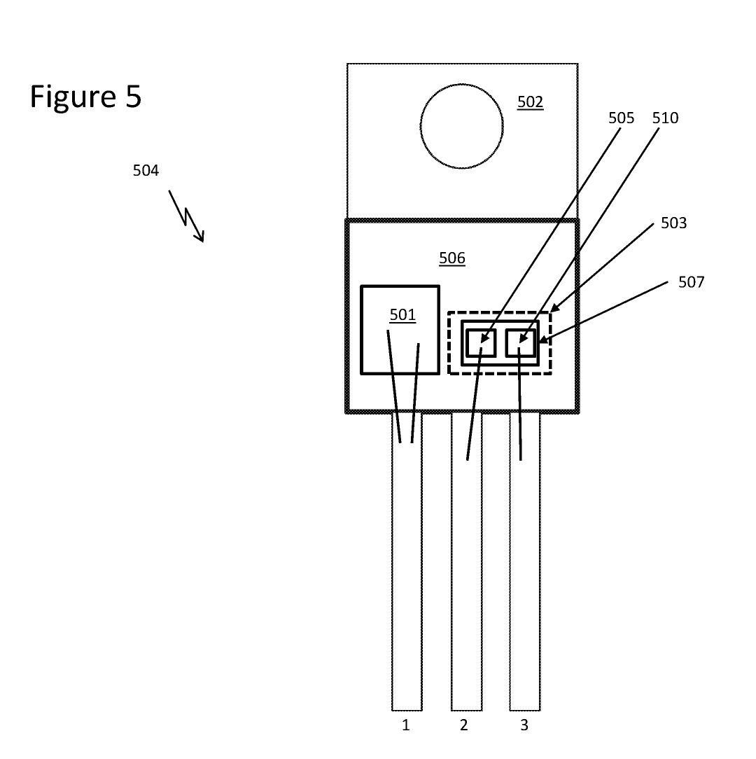

FIG. 5 shows a view of an example device 504 with a small lateral diode 507 co-packaged with a large silicon diode 501. The lateral diode 507 has an anode pad 50 and a cathode pad 505 on its top surface. The lateral diode 507 is a wide bandgap device that may be used, for example, as a boost diode in a PFC circuit. The lateral diode 507 may be, for example, a GaN HEMT-like lateral Schottky diode. Lateral diode 507 may be mounted on a direct bond copper (DBC) ceramic plate 503 that is thermally conductive but electrically insulating. Plate 503 may in turn be mounted on the common die pad 506. By this method, lateral diode 507 may be electrically isolated from the common die pad 506 but thermally connected to the common die pad 506. The anode 510 of the lateral diode 507 is connected to pin 3 of the package. The cathode 505 of the lateral diode 507 is connected to pin 2.

The silicon diode die 501 may be directly attached to the package common copper die pad 506. The silicon diode 501 may be a relatively large device that may be used, for example, as a bypass diode in a PFC circuit. The anode of large silicon diode 501 is connected to pin 1 of the package. The common die pad 502 and the cathode of the lateral diode 507 are connected to the center pin 2 of the package, thus forming a common cathode with the silicon diode.

Device 504 is depicted as being implemented in a TO-220 package, where tab 502 is connected to the common pin 2 and may serve as a thermal heat sink connection. Further, device 504 is depicted with a particular pin arrangement. It will be appreciated, however, that the device could be implemented in a number of ways, including using a variety of through-hole and surface mount packages, as well as with a variety of pin configurations.

The present invention may be understood more readily by reference to the following detailed description taken in connection with the accompanying figures and examples, which form a part of this disclosure. It is to be understood that this invention is not limited to the specific devices, methods, applications, conditions or parameters described and/or shown herein, and that the terminology used herein is for the purpose of describing particular embodiments by way of example only and is not intended to be limiting of the claimed invention. Also, as used in the specification including the appended claims, the singular forms “a,” “an,” and “the” include the plural, and reference to a particular numerical value includes at least that particular value, unless the context clearly dictates otherwise. The term “plurality”, as used herein, means more than one. When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable.

It is to be appreciated that certain features of the invention which are, for clarity, described herein in the context of separate embodiments, may also be provided in combination in a single embodiment. Conversely, various features of the invention that are, for brevity, described in the context of a single embodiment, may also be provided separately or in any sub-combination. Further, references to values stated in ranges include each and every value within that range.

In describing preferred embodiments of the subject matter of the present disclosure, as illustrated in the figures, specific terminology is employed for the sake of clarity. The claimed subject matter, however, is not intended to be limited to the specific terminology so selected, and it is to be understood that each specific element includes all technical equivalents that operate in a similar manner to accomplish a similar purpose. When ranges are used herein for physical properties, such as chemical properties in chemical formulae, all combinations, and subcombinations of ranges for specific embodiments therein are intended to be included

Those skilled in the art will appreciate that numerous changes and modifications can be made to the preferred embodiments of the invention and that such changes and modifications can be made without departing from the spirit of the invention. It is, therefore, intended that the appended claims cover all such equivalent variations as fall within the true spirit and scope of the invention.

What is claimed:

1. A device, comprising:
a junction barrier Schottky (JBS) diode made from a wide bandgap material
a silicon diode; and
a common package comprising a first terminal and a second terminal,
where:
the JBS diode and the silicon diode are mounted in the common package;
the first terminal is connected to the anode of the JBS diode;
the second terminal is connected to the anode of the silicon diode; and
the first and second terminals are separate.

2. The device of claim 1 where the silicon diode is at least 1.5× larger than the JBS diode in die area.

3. The device of claim 2, further where:
the common package comprise a third terminal; and
the third terminal is connected to the cathode of the JBS diode and to the cathode of the silicon diode.

4. The device of claim 3, wherein the JBS diode is made of silicon carbide, gallium nitride, aluminum nitride, aluminum gallium nitride, and/or diamond.

5. The device of claim 4, wherein the JBS diode is a diode-connected transistor.

6. The device of claim 5, wherein the JBS diode is bonded to a direct bond copper (DBC) ceramic plate, and the DBC ceramic plate is bonded to the common package.

7. The device of claim 6, wherein the JBS diode is a diode-connected high-electron-mobility transistor (HEMT).

8. The device of claim 4, wherein the common package is a TO-220 or TO-247 package.

9. A power circuit comprising the device of claim 4.
